(19) United States
(12) Patent Application Publication
(10) Pub. No.: US 2012/0111506 A1
(43) Pub. Date: May 10, 2012

(54) METHOD FOR THE CONTROLLED EVAPORATION OF A LIQUID DROP IN A MICROFLUIDIC DEVICE

(75) Inventor: Arnaud RIVAL, Charnecles (FR)

(73) Assignee: COMMISSARIAT A L'ENERGIE ATOMIQUE ET AUX ENE ALT, Paris (FR)

(21) Appl. No.: 13/292,627

(22) Filed: Nov. 9, 2011

(30) Foreign Application Priority Data
Nov. 10, 2010 (FR) 10 59293

(51) Int. Cl. B01D 1/00; B81B 1/00

(52) U.S. Cl. 159/23; 159/47.1; 159/22

(57) ABSTRACT

The invention relates to a method for the controlled evaporation of a liquid drop (2) in a closed or confined type microfluidic device (1), enabling the concentration of analytes possibly present in the drop (2) to be increased.

According to the invention, a drop (2) and/or a bubble (4) are brought into contact with each other, said contact enabling the drop (2) to evaporate in the bubble (4).

### TECHNICAL FIELD

The present invention relates generally to the field of liquid sample preparation in a microfluidic device, for chemical and/or biological applications.

The liquid sample comes as a drop and is located in a closed or confined type microfluidic device. More precisely, the drop is located between two walls of the device and is surrounded by a liquid non-miscible with it.

The invention is concerned with a method for the controlled evaporation of a liquid drop located in such a microfluidic device.

The drop can include analytes, for example chemical and/or biological particles, such as macromolecules, cells, organites, pathogens, or even intercalating agents.

When such is the case, the invention is also concerned with a method for increasing the concentration of the analytes in the drop.

### STATE OR PRIOR ART

In numerous fields, it is frequent to attempt to analyse liquid samples, in particular in order to know the concentration of analytes they can possible contain.

It is the case in particular in the fields of diagnostics, agro-food tracking or environmental monitoring.

For this, so called “lab-on-chip” type microfluidic devices can be used, which enable small liquid volumes to be efficiently handled.

It is thus possible to perform on a same support of a microfluidic device all the analysis steps of a liquid sample in a relatively short time and by using small sample and reagent volumes.

These analysis steps often include, prior to the detection of analytes and to measurement of the concentration thereof in the drop, a step for increasing the concentration of analytes to provide an efficient and accurate detection by known analysis means.

By way of illustration, FR 2 887 983, on behalf of the applicant, describes a microfluidic device and a method enabling the concentration of analytes present in a liquid sample to be increased.

As shown in FIGS. 1 and 2, this microfluidic device includes a substrate 10 with a liquid sample as a drop 2 thereon. The drop 2 includes analytes at a first concentration. The drop 2 is attempted to be evaporated to decrease the volume thereof, thus increasing the concentration of analytes. The analyte detection and analysis are thus improved.

The substrate 10 is provided with an array of independent electrodes 12 and the drop 2 is in contact with a counter-electrode 22 suspended above the substrate 10 (FIG. 2). It is separated from the electrodes 12 by a dielectric layer 14 covered with a hydrophobic layer 13. The drop 2 is moreover surrounded by gas.

By successively actuating the electrodes 12, the drop 2 is moved by electrowetting on the substrate 10, that is by changing the wetting angle of the drop 2 because of the application of an electrical field between the array of electrodes 12 and the counter-electrode 12.

When moving on the substrate 10, the drop 2 evaporates in the surrounding gas, with an evaporation rate higher than when the drop 2 remains motionless on the substrate 10.

Thus, the volume of the drop is decreased by evaporation.

When the drop comprises analytes, the concentration of analytes increases as the drop volume decreases.

It is worthy of note that this microfluidic device is a so-called “open” device insofar as the drop rests on a single substrate and is surrounded by gas and not liquid.

It is thus to be distinguished from the “closed” or “confined” type devices wherein the drop is located or even confined between two parallel walls and surrounded by a liquid non-miscible with the drop liquid.

By drop confined between two walls, it is meant a drop in contact with said walls. It can have a thickness defined by the distance between the walls, which is lower than its diameter.

FIG. 3 illustrates an exemplary closed or confined type microfluidic device.

The drop 2 is confined between two hydrophobic parallel walls 11, 21. These walls 11, 21 are formed by the surfaces of a lower substrate 10 and a upper substrate 20 facing each other.

The lower substrate 10 is similar or identical to that of the device described in FIG. 2. It is provided with an array of independently actuable electrodes 12. The array of electrodes 12 is covered with a dielectric layer 14 and a first hydrophobic layer 13. The upper substrate 12 comprises a counter-electrode 22 covered with a second hydrophobic layer 23.

The drop 2 is surrounded by a surrounding liquid 3 non-miscible with the liquid of the drop 2.

The drop movement principle is here identical to that previously described in reference to the open type microfluidic device.

Other exemplary closed or confined type microfluidic devices can be found in the article by Pollack et al. entitled “Electrowetting-based actuation of droplets for integrated microfluics”, Lab Chip, 2002, 2 (1), 96-101.

It appears that the method for decreasing the volume by evaporation of the drop and thus for increasing the concentration of analytes possibly present in the drop such as described above is not likely to be used in the closed or confined type microfluidic device.

Indeed, in such a device, the drop is surrounded by a non-miscible liquid, for example silicone oil, which prevents any evaporation of the drop, and therefore any controlled decrease in its volume.

### DESCRIPTION OF THE INVENTION

One object of the invention is to provide a method for the controlled evaporation of a liquid drop located in a closed or confined microfluidic device.

To do so, one object of the invention is a method for the controlled evaporation of a drop of a first liquid, said drop being located between two walls of a microfluidic device and surrounded by a second liquid non-miscible with the first liquid.

According to the invention, said drop and/or a bubble present between said walls are brought into contact with each other, said contact enabling the drop to evaporate in the bubble.

By evaporation, it is meant herein the spontaneous transformation of the liquid phase of the drop into gas phase in the bubble. Therefore, this can be described as a spontaneous evaporation.

Thus, within the scope of the present invention, the gas of the bubble has a vapour partial pressure of the first liquid substantially lower than the saturation vapour pressure thereof, such that when the drop and the bubble are in contact with each other, there is a spontaneous evaporation of the first liquid in the bubble.

It is worthy of note that the contact between the bubble and the drop can be direct, that is the bubble and the drop form an interface bounding the first liquid and the gas thereon. The liquid of the drop is thus directly in contact with the bubble.

The contact between the bubble and the drop may not be direct, in that a thin film of a second liquid is present between the bubble and the drop. However, the minimum thickness of this film of second liquid between the “bubble/second liquid” interface and the “drop/second liquid” interface is low enough not to prevent the spontaneous evaporation of the first liquid of the drop in the bubble. The minimum thickness of this film of second liquid is in the order of magnitude, or lower, than the mean diffusion length of molecules of the first liquid of the drop into the second liquid. Thus, the spontaneous evaporation is effective in spite of the presence of this film of second liquid.

The invention also relates to a method for increasing the concentration of analytes present in a drop of a first liquid, said drop being located between two walls of a microfluidic device and surrounded by a second liquid non-miscible with the first liquid.

According to the invention, the method for the controlled evaporation of said drop is implemented according to the previous characteristic, the decrease in the drop volume by evaporation causing the increase in the concentration of analytes in the latter.

During the evaporation of the drop in the bubble, the volume of the drop is advantageously measured.

During the evaporation of the drop in the bubble, the drop and/or the bubble are advantageously moved away from each other so as to stop evaporation of the drop in the bubble, when the bubble has a determined volume lower than the initial volume.

By initial volume, it is meant the drop volume before the evaporation step.

During the evaporation of the drop in the bubble, the bubble and possibly the drop can be heated, so as to increase the evaporation rate of the drop in the bubble.

By evaporation rate, it is meant the amount of the first liquid of the drop evaporated in the bubble per unit time.

The bubble and possibly the drop can be brought to a temperature between 50° C. and the boiling temperature of the first liquid of the drop, preferably between 70° C. and 95° C.

According to a first embodiment of the invention, the drop is brought in contact with the bubble by electrowetting under the effect of an electrical command.

One of the first and second liquids is then electrically conducting and the other is dielectric. Preferably, the first liquid is electrically conducting and the second liquid is dielectric.

According to a second embodiment of the invention, said drop is brought into contact with the bubble by liquid dielectrophoresis under the effect of an electrical command.

The first and second liquids thus have dielectric coefficients different from each other.

According to a third embodiment of the invention, said bubble is brought into contact with the drop by thermal expansion of the bubble, by heating it.

Subsequently to the evaporation step, the bubble can be discharged off the space bounded by said walls through a port provided at either said wall.

Prior to the evaporation step, the bubble can be introduced between said walls by a port provided at either said wall.

The invention also relates to a microfluidic device including two walls between which a drop of a first liquid is located surrounded by a second liquid non-miscible with the first liquid.

According to the invention, it includes means for moving said drop and/or bubble present between said walls, said moving means being capable of bringing said bubble and/or said drop into contact with each other, said contact enabling the drop to evaporate in the bubble.

Preferably, the means for moving said bubble and/or said drop are able to move the drop and/or the bubble away from each other so as to stop evaporation of the drop in the bubble.

Advantageously, the microfluidic device includes means for measuring the drop volume.

It includes, preferably, means for heating the bubble and possibly the drop, so as to increase the evaporation rate during the evaporation of the drop in the bubble.

Said heating means can comprise an electrical resistance provided in the proximity of the bubble and possibly of the drop and/or means for emitting an electromagnetic radiation.

The means for moving said bubble and/or drop can comprise electrical means for moving the drop by electrowetting or by liquid dielectrophoresis.

The means for moving said bubble and/or drop can alternatively comprise means for heating the bubble so as to ensure the thermal expansion of the bubble.

The microfluidic device can also include means for introducing and/or discharging the bubble through either said wall.

Further advantages and characteristics of the invention will appear in the non-limiting detailed description below.

### BRIEF DESCRIPTION OF THE DRAWINGS

Embodiments of the invention, by way of non-limiting examples, will now be described by referring to the accompanied drawings, wherein:

FIG. 1, already described, is a top view schematic representation of an open type microfluidic device according to prior art, enabling the volume of a drop to be decreased by evaporation;

FIG. 2, already described, is a partial longitudinal cross-section view of the open type microfluidic device represented in FIG. 1;

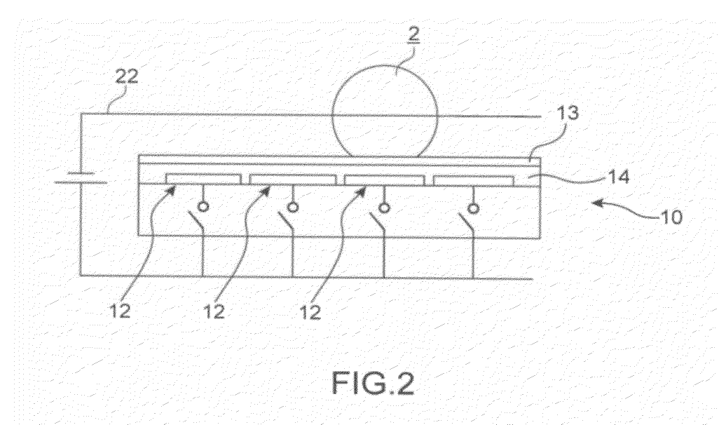

FIG. 3, already described, is a longitudinal cross-section schematic representation of the closed or confined type microfluidic device according to prior art;

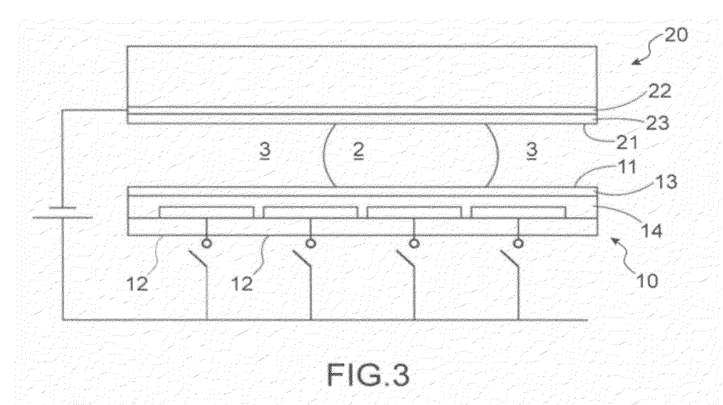

FIG. 4 is a longitudinal cross-section schematic representation of a part of the closed or confined type microfluidic device according to an embodiment of the present invention;

FIG. 5 is a top view of the microfluidic device represented in FIG. 4; and

FIGS. 6 to 8 are partial top views of the microfluidic device according to another embodiment of the invention, illustrating the movement by thermal expansion of the bubble to the drop, for three different moments.

### DETAILED DESCRIPTION OF THE PREFERED EMBODIMENTS

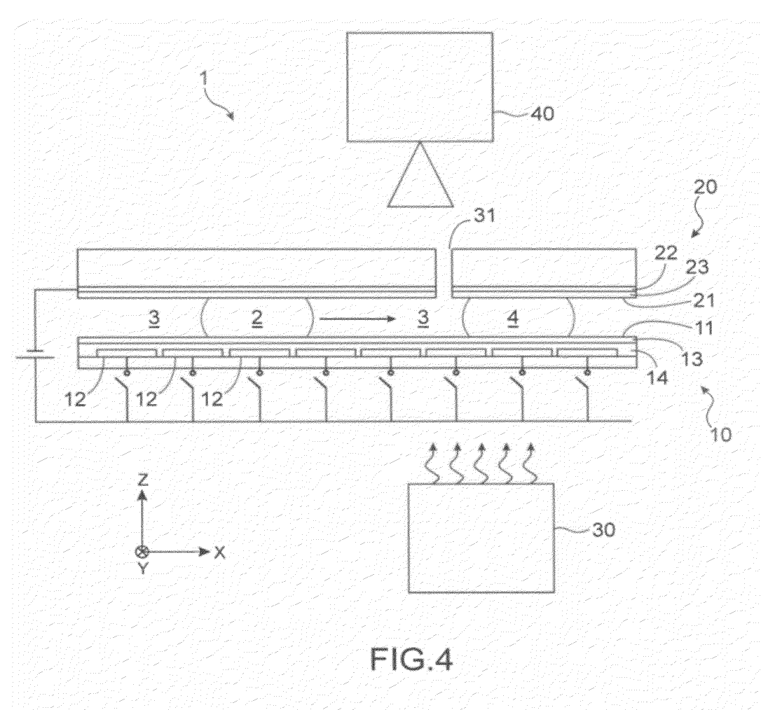

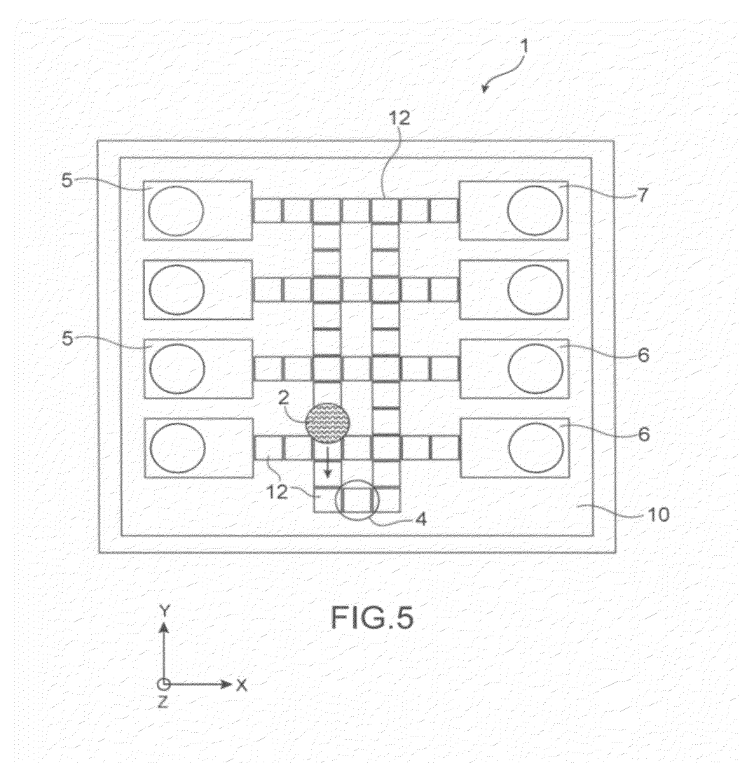

In FIGS. 4 and 5 a microfluidic device 1 is represented enabling the controlled evaporation of a drop and the increase in the concentration of analytes possibly present in the drop according to a first embodiment of the invention.

It is to be noted that the scales are not respected for clarity purposes.

In the description that follows, the verbs “cover”, “be located on” and “be provided on” do not necessarily imply a direct contact herein. Thus, a material or liquid can be provided on a wall without a direct contact between the material and the wall. An intermediate material can thus be present. The direct contact is made when the word “directly” is used with the verbs previously mentionned.

The microfluidic device 1 according to the invention comprises two walls 11, 21 between a drop 2 of a first liquid and a gas bubble 4 which are located, or even confined.

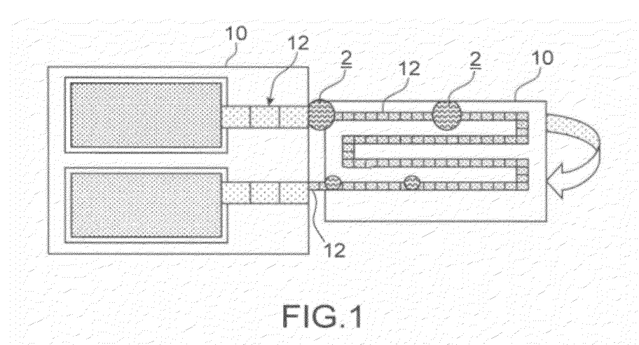

Throughout the description that follows, by convention, a direct orthonormal reference frame in Cartesian coordinates (X,Y,Z) shown in FIG. 1 is used. The plane (X,Y) is parallel to said walls 11, 21 and the direction Z is orthogonal to the walls 11, 21.

The terms “lower” and “upper” are to be understood herein in terms of orientation along the direction Z of said reference frame.

The drop 2 and the bubble 4 are said confined when each of them is in contact with both walls 11, 21 simultaneously. They can have a thickness substantially higher than their diameter. The thickness of the drop 2 and the bubble 4 is herein defined by the distance between both walls 11, 21.

The drop 2 and the bubble 4 are surrounded by a second liquid 3 non-miscible with the first liquid.

The space bounded by said walls 11, 21 is thus filled with a second liquid 3 and comprises the drop 2 and the bubble 4.

The microfluidic device 1 comprises means for moving the bubble 4 and/or the drop 2 which are capable of bringing the bubble 4 and/or the drop 2 into contact with each other, said contact enabling the drop 2 to be evaporated in the bubble 4.

According to the embodiment represented in FIGS. 4 and 5, these moving means ensure movement of the drop 2 to the bubble 4 by electrowetting, more precisely by electrowetting on dielectric (EWOD).

The microfluidic device 1 comprises a lower substrate 10 and an upper substrate 20 forming a cap, facing each other.

The lower substrate 10 includes an array of electrodes 12 which can be independently actuated from each other.

The array of electrodes 12 is covered with a dielectric layer 14 and a hydrophobic layer 13. The free surface of the hydrophobic layer 13 forms a wall 11 amongst both walls 11, 21 of the microfluidic device 1.

The cap 20 comprises a counter-electrode 22 covered with a second hydrophobic layer 23. The free surface of the second hydrophobic layer 23 forms the second wall 21 amongst both walls 11, 21 of the microfluidic device 1.

The hydrophobicity of the hydrophobic layers 13, 23 means that the drop 2 has, at rest, that is when the electrode 12 located below the drop 2 is not actuated, a contact angle, on these layers, higher than 90°.

The first liquid of the drop 2 is electrically conducting and the second liquid 3 is dielectric. The drop 2 forms an interface with this liquid 3.

The electrodes 12 and the counter-electrode 22 are connected to a voltage source enabling a voltage U to be applied between the electrodes.

When the electrode 12 facing the interface is actuated, using switching means the closing of which makes a contact between this electrode 12 and the voltage source via a common conductor, the set of the drop 2 under voltage, dielectric layer 14 and actuated electrode 12 acts as a capacitance.

As set out in the article by Berge entitled “Electrocapillarité et mouillage de films isolants par l'eau” C.R. Acad. Sci., 317, series 2, 1993, 157-163, the contact angle θ of the liquid interface is expressed as the relationship:

$$cos θ ( U ) = cos θ ( 0 ) + \frac{{ɛ}_{r}}{2 e σ} {U}^{2}$$

where e is the thickness of the dielectric layer 14, εᵣ is the permittivity of this layer 14 and σ is the surface tension of the first liquid interface.

When the bias voltage U is alternating, the first liquid behaves as a conductor insofar as the frequency of the bias voltage is substantially lower than a cut off frequency. The latter, which depends in particular on the electrical conductivity of the liquid, is typically in the order of a few tens of kilohertz (see for example the article by Mugele et Baret entitled “Electrowetting: from basics to applications”, J. Phys. Condens. Matter, 17 (2005), R705-R774). Besides, the frequency if preferably substantially higher than the frequency corresponding to the hydrodynamic response time of the liquid, which depends on physical parameters such as surface tension, viscosity or distance between both walls 11, 21, and which is in the order of a few tens or hundreds of Hertz. The response of the liquid then depends on the voltage root mean square, since the contact angle depends on the voltage in U², according to the previous relationship.

An electrostatic pressure acting on the interface then occurs, in the proximity of the contact line, as explained in the article by Bavière et al. entitled “Dynamics of droplet transport induced by electrowetting actuation”, Microfluid Nanofluid, 4, 2008, 287-294. The drop 2 can then be moved stepwise, on the hydrophobic surface 13, by successively actuating the electrodes 12 to the bubble 4.

It is to be noted that the bubble 4 is not substantially affected by the movement of the drop 2 and remains substantially motionless.

The handling of the drop 2 is located in a plane, since the electrodes 12 can indeed be linearly provided, but also in two dimensions, thus defining a movement plane for the drop (FIG. 5). The electrodes 12 thus form a fluid path which connects liquid sample tanks 5, reagent tanks 6 and drop discharging wells 7.

The microfluidic device 1 comprises means 30 for heating the bubble 4, and possibly the drop 2, for increasing the gas temperature of the bubble 4 and possibly the first liquid of the drop 2, when the latter is in contact with the bubble 4. When the bubble 4 is heated, the evaporation rate decreases. Moreover, the amount of first liquid which can be evaporated in the bubble 4 is increased, insofar as the saturation vapour pressure value is higher.

These heating means 30 can comprise a Joule effect electrical resistance provided so as to be able to heat the bubble 4 and possibly the drop 2.

They can also comprise a Peltier effect thermoelectrical module.

These heating means 30 can be provided in contact with or away from either substrate 10, 20.

They can also comprise means for emitting an electromagnetic radiation, for example in infrared. In this case, the radiation passes through the substrate which is substantially transparent to the wavelength of said radiation.

The device 1 can also comprise control means (not represented) enabling the temperature in the bubble and/or in the drop to be measured. It can be, for example, a temperature probe provided in contact with the substrate, preferably in the proximity of the bubble or the drop, this probe driving the heating means as a function of the temperature measured. The driving can be a PID (proportional-plus-integral-plus-derivative) type.

The microfluidic device 1 comprises means 40 for measuring the volume of the liquid drop 2.

These measuring means 40 can include a direct light type optical microscope. The viewing is preferably performed through the cap 20, in which case the latter is transparent.

These measuring means 40 comprise a shot managing and data storing unit, for post-processing and analysing the sequences of images performed.

The images can thus be digitized in real time and the outline of the drop is detected in post-processing using an image processing software. Calculating means then allow to deduce the drop volume.

Control means (not represented) allow to control or actuate the electrodes 12 one by one, for example a PC type computer connected to the switching means.

This control means are also connected to the heating means 30, to the temperature controlling means as well as the means 40 for measuring the drop volume.

Thus, the user can control the movement of the drop 2 to the bubble 4, speed up or slow down the evaporation of the drop 2 in the bubble 4 and accurately control the decrease in the volume of the drop 20. This control is performed by acting on the proximity of the drop and the bubble, or on the heating means previously described.

The lower substrate 10 or the cap 20 can include at least one port 31 going through and opening at either one of said wall 11, 21.

This port enables the bubble to be introduced between the walls of the device and/or to be removed therefrom.

It can be connected to bubble generating means, for example a gas tank and means for increasing the pressure in the tank. The connection between the tank and the device can be ensured by a needle passing through the port 31, the latter being sealed by a septum.

The port 31 can also be connected to the air surrounding the microfluidic device 1 when all or part of the bubble 4 is desired to be removed.

The port 31 is preferably sealed when said bubble is not desired to be introduced or removed.

When the port 31 enables the gas included in the air bubble 4 to be discharged, it acts as vent. This port ensures a communication between the space confined between both substrates 10, 20 and the medium outside the device, so as to enable all or part of the gas present in the bubble 4 outside the device to be discharged.

The area of the port is low enough to prevent the immiscible fluid to be discharged. Its diameter can for example be lower than the capillary length of the immiscible liquid 3 in the gas making up the medium outside the device. Generally, this diameter (or the largest width in the case of a non-circular port 31) is preferably between 100 μm and 5 mm, and more preferably between 100 μm and 1 mm, for example 500 μm.

The gas bubble 4 can be moved facing the port by being pushed by the drop 2, the latter being moved by the moving means, for example by electrowetting. Thus, the bubble 4, after growing under the effect of evaporation of part of the drop 2, can be brought into contact with the port, until its volume is decreased.

According to an alternative, it is the increase in the volume of the bubble 4, when placed into contact with the drop 2, that enables the bubble to come into contact with the port 31.

It can be seen that the presence of the port 31 is a means for regulating the size of the bubble 4. Thus, the presence of such a port, acting as a vent, will be preferred in all the embodiments.

It is to be noted that the bubble 4 can also be formed during the prior introduction of the second liquid 3 between both walls 11, 21. A bubble 4 can indeed be generated at a corner formed by both walls 11, 21 on the one hand and one or both adjacent side walls on the other hand. For this, before introducing the second liquid 3, a partial vacuum is provided in the device, for example 0.1 mbar, and then it is filled with the second liquid 3, for example oil, the filling being performed at atmospheric pressure. Thus, oil 3 replaces the initially formed partial vacuum. Since this vacuum is partial, a gas bubble 4 can be formed in a corner of the device.

The lower substrate 10 and the cap 20 are preferably made up of a transparent material, for example glass or polycarbonate.

Spacing wedges enable both substrates 10, 20 to be spaced apart. They are preferentially made of a Ordyl type photo-imageable dry film.

The spacing between the lower substrate 10 and the upper substrate 20 is typically between 10 μm and 500 μm, and preferably between 50 μm and 100 μm.

The electrodes 12 and counter-electrode 22 are made by depositing a material, preferably transparent, for example ITO, onto the substrate. This conducting layer can be sprayed or made in a sol-gel method. It is then etched according to a suitable pattern, for example by wet etching.

The thickness of the electrodes 12 is between 10 nm and 1 μm, preferably 300 nm. The electrodes 12 are preferably square with a side the length of which is between a few micrometres to a few millimetres, preferably between 50 μm and 1 mm. The area of the electrodes 12 depends of the size of the drops to be conveyed. The spacing between neighbouring electrodes can be preferably between 1 μm and 10 μm.

The dielectric layer 14 is made by depositing a silicon nitride Si₃N₄ layer, with a thickness generally between 100 nm and 1 μm, preferably 300 nm. A plasma enhanced chemical vapour deposition (PECVD) is preferred to the low pressure chemical vapour deposition (LPCVD) for thermal reasons. Indeed, the substrate temperature is only brought between 150° C. and 350° C. (depending on the required properties) versus about 750° C. for LPCVD deposition.

The hydrophobic layers 13, 23 are obtained by vacuum evaporation deposition of Teflon or SiOC, or parylene, for example, on the lower 10 and upper 20 substrates. These layers 13, 23 enable in particular to decrease or even to prevent the hysteresis effect of the wetting angle. Their thickness, generally between 100 nm and 5 μm, is preferably 1 μm.

The port 31 for introducing and/or discharging the bubble can have a diameter between 100 μm and 2 mm.

The first liquid is electrically conducting and can be water or saline.

The second liquid is dielectric and non-miscible with the first liquid. It can be, for example, a mineral or silicone oil.

The drop and the bubble can have a volume between 0.1 nanolitre and 1 microlitre. The bubble gas can be air.

The operation of the microfluidic device according to the first embodiment of the invention is as follows.

As shown in FIG. 4, a bubble 4 is present between both walls 11, 21 of the microfluidic device 1.

It can be formed during the introduction of the second liquid 3 between the walls 11, 21, or introduced by suitable means.

A drop 2 is also present between both walls 11, 21. It is away from the bubble 4 and surrounded by the second liquid 3, so that it does not have spontaneous evaporation.

The drop 2 is moved by electrowetting by successively actuating the electrodes 12 to bring it into contact with the bubble 4, said contact enabling the drop 2 to spontaneously evaporate in the bubble 4.

The drop 2 can thus be in direct contact with the bubble 4. Part of its interface is defined by bounding the first liquid of the drop 2 and the gas of the bubble 4.

At this part of interface, the first liquid of the drop 2 naturally evaporates in the gas of the bubble 4.

For the spontaneous evaporation to occur, the gas of the bubble 4 has a vapour partial pressure of the first liquid substantially lower than the saturation vapour pressure of this first liquid.

It is to be noted that a thin film of the second liquid 3 can however separate the drop 2 from the bubble 4, without preventing the drop 2 from evaporating in the bubble 4.

In this case, this film has a minimum thickness between the “bubble/second liquid” interface and “drop/second liquid” interface.

For the spontaneous evaporation of the drop 2 to occur in the bubble 4 despite the presence of this film, the minimum thickness thereof is in the order of, or lower than, the average diffusion length of molecules of the first liquid of the drop 2 in the second liquid 3.

This thickness is in particular dependent on the local temperature at the film of second liquid 3 and of the drop 2. Indeed, the mean diffusion length increases with temperature, by molecular stirring.

By way of illustration, the molecular diffusivity of water in oil is in the order of 10¹⁰ m²/s. Thus, a characteristic diffusion length of molecules of the first liquid through the film of second liquid, for a characteristic time of 1 s, is in the order of 10 μm.

Also, this minimum film thickness of the second liquid 3 between the drop 2 and the bubble 4 can be equal to or lower than 100 μm, for example between 100 μm and 1 nm, preferably between 10 μm and 1 nm, or even between 1 μm and 1 nm.

Thus, when the drop 2 and the bubble 4 are in contact with each other, with or without thin film of second liquid 3, the drop 2 spontaneously evaporates in the bubble 4.

It is worth of note that, during the evaporation step, the bubble 4 and possibly the drop 2 can be heated so as to bring it or them to a temperature higher than the room temperature. Thus, the evaporation rate of the drop in the bubble is increased. Moreover, the amount of first liquid which can be evaporated in the bubble 4 is higher because the saturation vapour pressure value is also increased.

However, the temperature remains lower than the boiling temperature of the drop 2.

In the case of the water drop 2 and air bubble 4, it can thus be between 25° C. and 95° C., preferably 50° C. and 95° C., or even 70° C. and 95° C. The evaporation of the drop in the bubble is all the quicker that the temperature of the drop increases.

The volume of the drop 2 is then measured in real time. More precisely, a sequence of images of the drop is recorded, these images are digitized and the outline of the drop 2 is detected therein by a processing software. The volume of the drop 2 is then deduced therefrom.

When the volume of the drop 2 has decreased to a determined value, lower than the initial volume defined prior to the evaporation step, the drop 2 is sufficiently moved away from the bubble 4, by electrowetting, to prevent any further evaporation of the drop 2 in the bubble 4.

In the case where the drop 2 comprises analytes, the concentration of analytes in the drop 2 is thus increased by the decrease in the volume of the drop 2 by evaporation.

When these analytes are labelled with a fluorescent agent, the fluorescence signal thus increases in intensity because of the increase in the concentration of analytes of the drop 2. The detection of analytes is made more precise.

It is to be noted that this method enables the drop 2 to be evaporated in a controlled and accurate manner, thus to decrease the volume thereof and to increase the concentration of analytes possibly present in the drop 2.

When the drop 2 and the bubble 4 are sufficiently away from each other to prevent any further evaporation, the drop 2 keeps a constant volume. The concentration of analytes possibly present is then also constant.

The microfluidic device according to a second embodiment of the invention (not represented) is now described.

This embodiment is distinguished from the first embodiment only as regards the means for moving the bubble 4 and/or the drop 2 in contact with each other.

According to this embodiment, these moving means are adapted to move the drop 2 by liquid dielectrophoresis, thus enabling the drop 2 to be brought into contact with the bubble 4 and to be moved away from it.

The first liquid of the drop 2 and the second liquid 3 can be electrically conducting or insulating. They however have a different dielectric coefficient from each other.

By liquid dielectrophoresis (LDEP), it is meant the application of an electrical force on a electrically insulating or conducting liquid, herein the first liquid of the drop, the force being generated by a non-uniform oscillating electric field.

The first liquid of the drop 2 has a dielectric coefficient substantially higher than that of the second liquid 3.

When the drop 2 is located in an electric field, the molecules of the first liquid acquire a non-zero dipole and polarize. Since the field is non-uniform, a Coulomb force appears and induces the movement of the liquid molecules, and thus all the entire drop, towards a field maximum.

The lower substrate 10 can comprise, as for the electrowetting, an array of electrodes, along one or two dimension(s) in the plane of the substrate 10, thus defining a fluid path for the drop 2. It can also comprise not one array of electrodes, but two electrodes parallel to each other, extending along one or two dimensions and then defining a fluid path for the drop 2.

These electrodes can be covered with a dielectric layer, depending on whether the first and second liquids are electrically conducting or not.

A hydrophobic layer covers the first substrate, thus defining one of both walls of the microfluidic device.

The second of both walls of the device is formed by the hydrophobic layer of the cap. The cap may not comprise a counter-electrode.

The voltage applied between the two parallel electrodes of the first substrate is an alternating voltage the frequency of which is between, for example, a few kilohertz and a few megahertz, for example between 10 kHz and 10 MHz, and between 10 kHz and 100 kHz, and of a preferential voltage from a few RMS volts to a few hundreds of RMS volts.

Thus, the drop can not be brought into contact with the bubble, said contact enabling the drop to evaporate in the bubble.

The method for decreasing the drop volume and increasing the concentration of analytes possibly present in the drop is identical to that described in reference to the first embodiment.

The microfluidic device according to the first embodiment of the invention is now described.

This embodiment is distinguished from the first embodiment only as regards the means for moving the bubble and/or the drop in contact with each other.

According to this embodiment, these moving means (not represented) are adapted to bring the bubble, by the thermal expansion thereof, into contact with the drop.

According to this embodiment, when the device has a port 31 acting as a vent, the air bubble can be moved by being pushed by immiscible liquid 3, when the latter is subjected to dielectrophoresis forces.

The method for decreasing the drop volume and increasing the concentration of analytes possibly present in the drop is identical to that described in reference to the first embodiment.

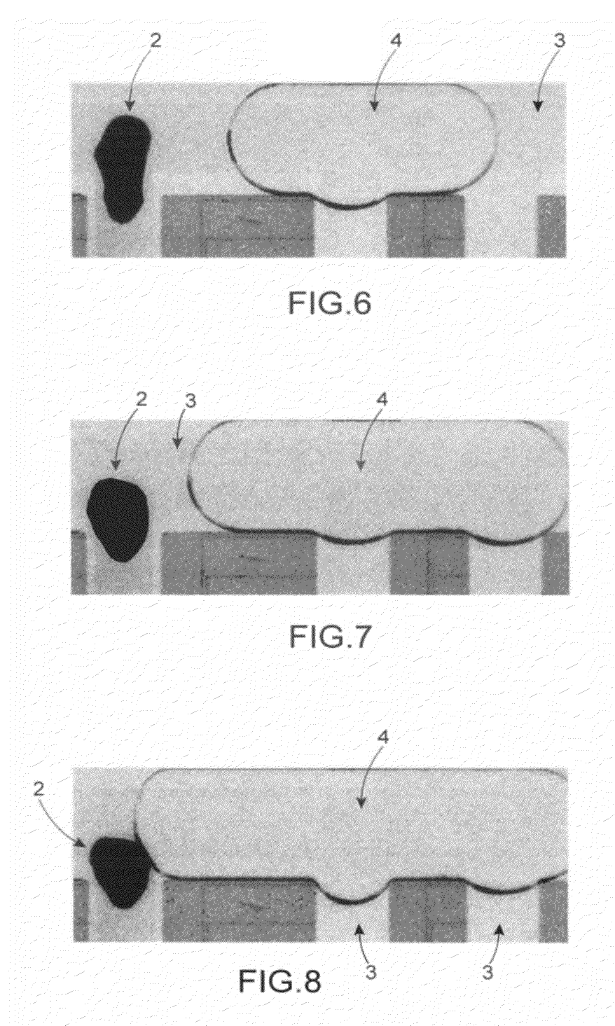

FIGS. 6 to 8 are partial top views of the microfluidic device, illustrating an example of the movement by thermal expansion of the bubble towards the drop.

These figures show a drop 2 and a bubble 4 located on a second liquid 3.

The drop 2 here comprises analytes labelled with a fluorescent agent. It is located on the figures by the fluorescence signal resulting therefrom.

Thus, by heating the bubble 4 (FIG. 6), the volume thereof is increased and a part of its interface is moved towards the drop 2 (FIG. 7).

It is worthy of note that these moving means do not enable the entire bubble 4 to be moved in a given direction. The barycentric rate of the bubble 4 actually remains substantially zero. By barycentric rate, it is meant the rate of the barycentre of the bubble 4.

These moving means can comprise a Joule effect electrical resistance provided so as to heat the bubble 4 and possibly the drop 2.

They can also comprise a Peltier effect thermo-electrical module.

These heating means can be provided in contact with or away from either substrate.

They can also comprise means for emitting an electromagnetic radiation, for example in infrared. In this case, this radiation passes through the substrate which is substantially transparent to the wavelength of said radiation.

The device can also comprise control means enabling the temperature in the bubble and/or in the drop to be measured, for example a temperature probe connected to the heating means, such as described previously.

Thus, these moving means enable a part of the bubble 4 to be brought into contact with the drop 2 (FIG. 8), said contact enabling the drop 2 to evaporate in the bubble 4.

Thus, by a decrease in the volume of the drop 2 by evaporation, the concentration of analytes in the drop 2 is increased.

This results in an increased intensity of the fluorescence signal because of the increase in the concentration of analytes in the drop 2. The detection of analytes is made more accurate.

Of course, various modifications can be made by those skilled in the art to the invention just described, only by way of non-limiting examples.

1. A method for the controlled evaporation of a drop (2) of a first liquid, said drop (2) being located between two walls (11, 21) of a microfluidic device (1) and surrounded by a second liquid (3) non-miscible with the first liquid,
characterised in that said drop (2) and/or a bubble (4) present between said walls (11, 21) are brought into contact with each other, said contact enabling the drop (2) to evaporate in the bubble (4).

2. The method for the controlled evaporation according to claim 1, characterised in that, during the evaporation of the drop (2) in the bubble (4), the volume of the drop (2) is measured.

3. The method for the controlled evaporation according to claim 2, characterised in that, during the evaporation of the drop (2) in the bubble (4), the drop (2) and/or the bubble (4) are moved away from each other so as to stop evaporation of the drop (2) in the bubble (4) when the drop (2) has a determined volume lower than the initial volume.

4. The method for the controlled evaporation according to claim 1, characterised in that, during the evaporation of the drop (2) in the bubble (4), the bubble (4) and possibly the drop (2) are heated so as to increase the evaporation rate of the drop (2) in the bubble (4).

5. The method for the controlled evaporation according to claim 4, characterised in that the bubble (4) and possibly the drop (2) are brought to a temperature between 50° C. and the boiling temperature of the first liquid of the drop (2).

6. The method for the controlled evaporation according to claim 1, characterised in that said drop (2) is brought into contact with the bubble (4) by electrowetting under the effect of an electrical command.

7. The method for the controlled evaporation according to claim 6, characterised in that one of the first and second liquids is electrically conducting and the other is dielectric.

8. The method for the controlled evaporation according to claim 1, characterised in that said drop (2) is brought into contact with the bubble (4) by liquid dielectrophoresis under the effect of an electrical command.

9. The method for the controlled evaporation according to claim 8, characterised in that the first and second liquids have different dielectric coefficients from each other.

10. The method for the controlled evaporation according to claim 1, characterised in that said bubble (4) is brought into contact with the drop (2) by thermal expansion of the bubble (4), by heating it.

11. The method for the controlled evaporation according to claim 1, characterised in that, subsequent to the evaporation step, the bubble (4) is discharged off the space bounded by said walls (11, 21) through a port (31) provided at either one of said walls (11, 21).

12. A method for increasing the concentration of analytes present in a drop (2) of a first liquid, said drop (2) being located between two walls (11, 21) of a microfluidic device (1) and surrounded by a second liquid (3) non-miscible with the first liquid,
characterised in that the method for the controlled evaporation according to one of the preceding claims is implemented for said drop (2), the decrease in the volume of the drop (2) through evaporation causing the increase in the concentration of analytes in the latter.

13. The method for increasing the concentration of analytes according to claim 12, characterised in that, prior to the evaporation step, the bubble (4) is introduced between said walls (11, 21) through a port (31) provided at either said walls (11, 21).

14. A microfluidic device including two walls (11, 21) between which is located a drop (2) of a first liquid surrounded by a second liquid (3) non-miscible with the first liquid,
characterised in that it includes means for moving said drop (2) and/or a bubble (4) present between said walls (11, 21), said means for moving being capable of bringing said drop (2) and/or said bubble (4) into contact with each other, said contact enabling the drop (2) to evaporate in the bubble (4).

15. The microfluidic device according to claim 14, characterised in that the means for moving said drop (2) and/or said bubble (4) are capable of moving said drop (2) and/or said bubble (4) away from each other so as to stop evaporation of the drop (2) in the bubble (4).

16. The microfluidic device according to claim 14, characterised in that it includes means (40) for measuring the volume of the drop (2).

17. The microfluidic device according to claim 14, characterised in that it includes means (30) for heating the bubble (4) and possibly the drop (2), so as to increase the evaporation rate during the evaporation of the drop (2) in the bubble (4).

18. The microfluidic device according to claim 17, characterised in that the heating means (40) comprise an electrical resistance provided in the proximity of the bubble (4) and possibly the drop (2), and/or means for emitting an electromagnetic radiation.

19. The microfluidic device according to claim 14, characterised in that the means for moving said drop (2) and/or said bubble (4) include electrical means for moving the drop (2) by electrowetting or by a liquid dielectrophoresis.

20. The microfluidic device according to claim 14, characterised in that the means for moving said drop (2) and/or said bubble (4) include means for heating the bubble (4) so as to ensure thermal expansion of the bubble (4).

21. The microfluidic device according to claim 14, characterised in that it includes means for introducing and/or discharging the bubble (4) through either one of said walls (11, 21).
